(19) United States
(12) Patent Application Publication
(10) Pub. No.: US 2025/0287790 A1
(43) Pub. Date: Sep. 11, 2025

(54) DISPLAY DEVICE AND ELECTRONIC DEVICE INCLUDING THE SAME

(71) Applicant: Samsung Display Co., Ltd., Yongin-Si (KR)

(72) Inventors: YEONGHO KIM, Yongin-si (KR); JONG-SIK PARK, Yongin-si (KR); SIEUN CHEON, Yongin-si (KR); SEUNGWOO KANG, Yongin-si (KR)

(21) Appl. No.: 19/004,459

(22) Filed: Dec. 30, 2024

(30) Foreign Application Priority Data
Mar. 11, 2024 (KR) 10-2024-0033682

(51) Int. Cl. H10K 59/124; H10K 59/122; H10K 59/40

(52) U.S. Cl. CPC H10K 59/124; H10K 59/122; H10K 59/40

(57) ABSTRACT

A display device includes a substrate that has a hole area in which a through-hole is defined, a display area that surrounds at least a portion of the hole area, and a hole peripheral area disposed between the hole area and the display area, an interlayer insulating layer disposed in the display area and the hole peripheral area on the substrate, a first stack structure disposed on the interlayer insulating layer and forming a first stepped portion having a first height in the hole peripheral area, and a second stack structure disposed on the first stack structure and forming a second stepped portion having a second height of at least 2.8 μm and no more than 4.0 μm in the hole peripheral area and the display area adjacent to the hole peripheral area.

### CROSS-REFERENCE TO RELATED APPLICATION(S)

This application claims priority, under 35 U.S.C. § 119, to Korean Patent Application No. 10-2024-0033682 filed on Mar. 11, 2024, which is hereby incorporated by reference for all purposes as if fully set forth herein.

### BACKGROUND

### 1. Field

Embodiments relate to a display device. More particularly, the embodiments relate to the display device having a hole area.

### 2. Description of the Related Art

A display device is a device that includes a display panel that displays an image to provide visual information to a user.

A functional module (e.g., a camera module, etc.) may be disposed on a display device and allow a user to perform various functions using the display device. To improve the efficiency of the functional module, a transmittance of external light that is incident on the functional module is increased. In addition, recently, in order to expand a display area of the display device, a structure in which the functional module overlaps the display area has been developed.

### SUMMARY

Embodiments provide a display device in which formation of defect-generating bubbles may be reduced or avoided.

A display device according to an embodiment may include a substrate including a hole area that has a through hole, a display area that surrounds at least a portion of the hole area, and a hole peripheral area disposed between the hole area and the display area, an interlayer insulating layer disposed in the display area and the hole peripheral area on the substrate, a first stack structure disposed on the interlayer insulating layer and forming a first stepped portion having a first height in the hole peripheral area, the first height being a distance between an upper surface and a lower surface of the first stack structure, and a second stack structure disposed on the first stack structure and forming a second stepped portion having a second height of at least 2.8 μm in the hole peripheral area and the display area, the second height being a distance between an upper surface and a lower surface of the second stack structure.

In an embodiment, the first height may be at least 2.8 μm.

In an embodiment, the first height and the second height may be substantially equal to each other.

In an embodiment, the first height and the second height may be different from each other.

In an embodiment, the display device may further include a first organic layer disposed in the hole peripheral area and the display area on the interlayer insulating layer and a second organic layer disposed in the hole peripheral area and the display area on the first organic layer.

In an embodiment, the first stack structure may include the first organic layer and the second organic layer, and an upper surface of the second organic layer, a side surface of the second organic layer facing the hole area, and an upper surface of the interlayer insulating layer may form the first stepped portion.

In an embodiment, the display device may further include a third organic layer disposed in the hole peripheral area and the display area on the second organic layer, a pixel defining layer disposed on the third organic layer, and a spacer disposed in the display area on the pixel defining layer.

In an embodiment, the second stack structure may include the third organic layer and the pixel defining layer, and an upper surface of the pixel defining layer, side surfaces of the third organic layer and pixel defining layer facing the hole area, and the upper surface of the second organic layer may form the second stepped portion.

In an embodiment, the second stack structure may include the pixel defining layer and the spacer. An upper surface of the spacer, side surfaces of the pixel defining layer and the spacer facing the hole area, and an upper surface of the third organic layer may form the second stepped portion.

In an embodiment, the third organic layer may be disposed between the first stack structure and the second stack structure.

In an embodiment, the display device may further include a pixel defining layer disposed in the display area on the second organic layer, and a spacer disposed in the display area on the pixel defining layer.

In an embodiment, the second stack structure may include the pixel defining layer and the spacer. An upper surface of the spacer, side surfaces of the pixel defining layer and the spacer acing the hole area, and the upper surface of the second organic layer may form the second stepped portion.

In an embodiment, the display device may further include a touch sensing layer disposed in the display area and the hole peripheral area on the second stack structure, an optical functional layer in the display area and the hole peripheral area on the touch sensing layer, a window layer disposed in the hole area, the hole peripheral area, and the display area on the optical functional layer, and a light-blocking member disposed in the window layer.

In an embodiment, the light-blocking member may have a single-layer structure.

In an embodiment, the light-blocking member may have a multi-layer structure.

In an embodiment, the touch sensing layer may contact the optical functional layer.

A display device according to an embodiment may include a substrate including a hole area that has a through hole, a display area that surrounds at least a portion of the hole area, and a hole peripheral area disposed between the hole area and the display area, an interlayer insulating layer disposed in the hole peripheral area and the display area on the substrate, a first organic layer disposed in the hole peripheral area and the display area on the interlayer insulating layer, a second organic layer disposed in the hole peripheral area and the display area on the first organic layer, a third organic layer disposed in the hole peripheral area and the display area on the second organic layer, and a pixel defining layer disposed in the hole peripheral area and the display area on the third organic layer. An upper surface of the second organic layer, a side surface of the second organic layer covering the first organic layer, and an upper surface of the interlayer insulating layer form a first stepped portion, and an upper surface of the pixel defining layer, side surfaces of the third organic layer and the pixel defining layer facing the hole area, and the upper surface of the second organic layer form a second stepped portion.

In an embodiment, a height of each of the first stepped portion and the second stepped portion may be at least 2.8 μm.

A display device according to an embodiment may include a substrate including a hole area that has a through-hole, a display area that surrounds at least a portion of the hole area, and a hole peripheral area disposed between the hole area and the display area, an interlayer insulating layer disposed in the hole peripheral area and the display area on the substrate a first organic layer disposed in the hole peripheral area and the display area on the interlayer insulating layer, a second organic layer disposed in the hole peripheral area and the display area on the first organic layer, a third organic layer disposed in the hole peripheral area and the display area on the second organic layer, a pixel defining layer disposed in the hole peripheral area and the display area on the third organic layer, and a spacer disposed in the display area on the pixel defining layer. An upper surface of the second organic layer, a side surface of the second organic layer covering the first organic layer, and an upper surface of the interlayer insulating layer form a first stepped portion, and an upper surface of the spacer, side surfaces of the pixel defining layer and the spacer facing the hole area, and the upper surface of the third organic layer form a second stepped portion.

In an embodiment, a height of each of the first stepped portion and the second stepped portion may be at least 2.8 μm.

An electronic device according to an embodiment may include a processor outputting an image data signal and an input control signal and a display device driving based on the image data signal and the input control signal. The display device may include a substrate including a hole area that has a through hole, a display area that surrounds at least a portion of the hole area, and a hole peripheral area disposed between the hole area and the display area, an interlayer insulating layer disposed in the display area and the hole peripheral area on the substrate, a first stack structure disposed on the interlayer insulating layer and forming a first stepped portion having a first height in the hole peripheral area, the first height being a distance between an upper surface and a lower surface of the first stack structure, and a second stack structure disposed on the first stack structure and forming a second stepped portion having a second height of at least 2.8 μm in the hole peripheral area and the display area, the second height being a distance between an upper surface and a lower surface of the second stack structure.

In the display device according to embodiments, the display device may include a first stack structure defining a first stepped portion having a first height in a hole peripheral area, and a second stack structure defining a second stepped portion having a second height in the hole peripheral area or a display area. Both the first height and the second height may be at least 2.8 μm. Accordingly, an inclination angle of a side surface of a second encapsulation layer facing a hole area may increase and become closer to vertical. Accordingly, an additional process of forming a member to compensate for a step between an optical function layer and a touch sensing layer may not be required, reducing process cost and time. In addition, a light-blocking member may have a single-layer structure, resulting in further reduction of process cost and time.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of present disclosure.

FIG. 2 is a circuit diagram illustrating a pixel included in the display device of FIG. 1.

FIG. 3 is a cross-sectional view illustrating a cross-section taken along a line I-I′ of FIG. 1.

FIG. 4 is a cross-sectional view illustrating an example of a cross-section of a display panel included in the display device of FIG. 1 in a display area.

FIG. 5 is a cross-sectional view illustrating an example of a cross-section of area A of FIG. 3.

FIG. 6 is a cross-sectional view illustrating a cross-section of area B1 of FIG. 5.

FIG. 7 is a cross-sectional view illustrating another example of a cross-section of area A of FIG. 3.

FIG. 8 is a cross-sectional view illustrating a cross-section of area B2 of FIG. 7.

FIG. 9 is a cross-sectional view illustrating another example of a cross-section of a display panel included in the display device of FIG. 1 in a display area.

FIG. 10 is a cross-sectional view illustrating still another example of a cross-section of area A of FIG. 3.

FIG. 11 is a cross-sectional view illustrating a cross-section of area B3 of FIG. 10.

FIG. 12 is a block diagram of an electronic device according to an embodiment of the present disclosure.

FIG. 13 is a schematic diagram of the electronic device according to various embodiments of the present disclosure.

### DETAILED DESCRIPTION OF THE EMBODIMENTS

Display devices in accordance with embodiments will be described in more detail with reference to the accompanying drawings. The same reference numerals are used for the same components in the drawings, and redundant descriptions of the same components will be omitted.

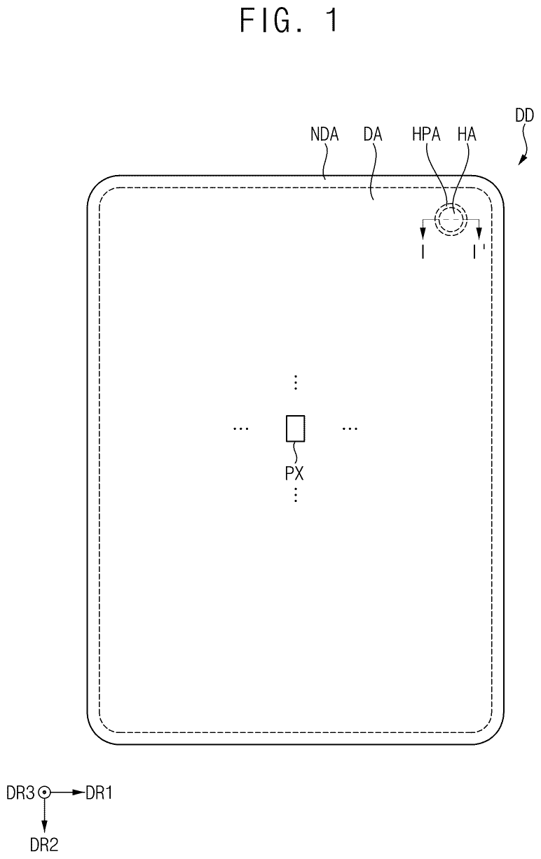

FIG. 1 is a plan view illustrating a display device according to an embodiment of present disclosure.

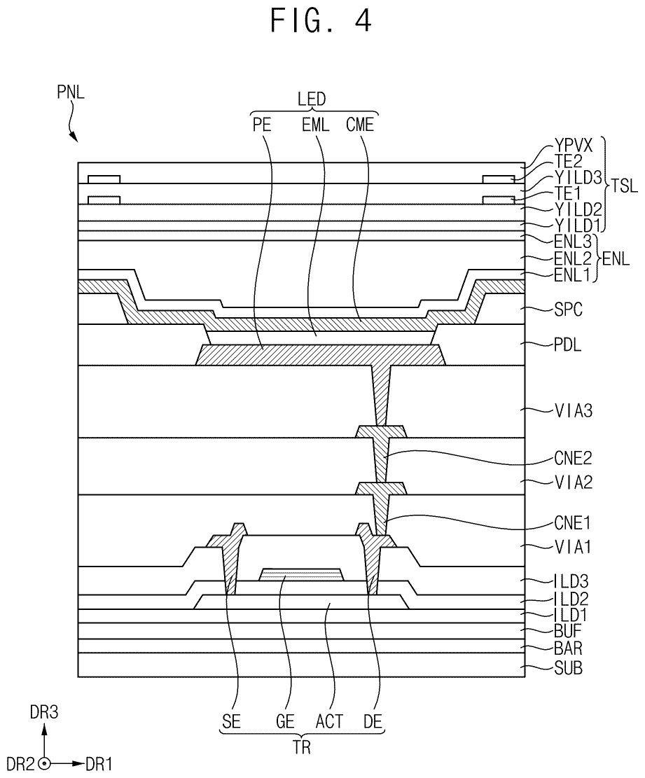

Referring to FIG. 1, a display device DD according to an embodiment of the present disclosure, the display device DD (e.g., a substrate SUB of FIG. 4) may include a display area DA, a non-display area NDA, a hole area HA, and a hole peripheral area HPA.

In this specification, a plane may be defined by a first direction DR1 and a second direction DR2. For example, the second direction DR2 may be perpendicular to the first direction DR1. In addition, the third direction DR3 may be perpendicular to the plane.

The display area DA may be defined as an area that displays an image by generating light or adjusting a transmittance of light provided from an external light source. At least one pixel PX may be disposed in the display area DA. The pixel PX may emit light. A plurality of pixels PX may be repeatedly arranged along the first direction DR1 and the second direction DR2 that intersects the first direction DR1. In addition, the pixel PX may include a plurality of sub-pixels that emit light of different colors. For example, the sub-pixels may include a red sub-pixel that emits red light, a green sub-pixel that emits green light, and a blue sub-pixel that emits blue light.

The non-display area NDA may be defined as an area that does not display images. The non-display area NDA may be adjacent to the display area DA. For example, the non-display area NDA may surround at least a portion of the display area DA. A driver electrically connected to the pixel PX may be disposed in the non-display area NDA. For example, the driver may include a data driver, a gate driver, and the like.

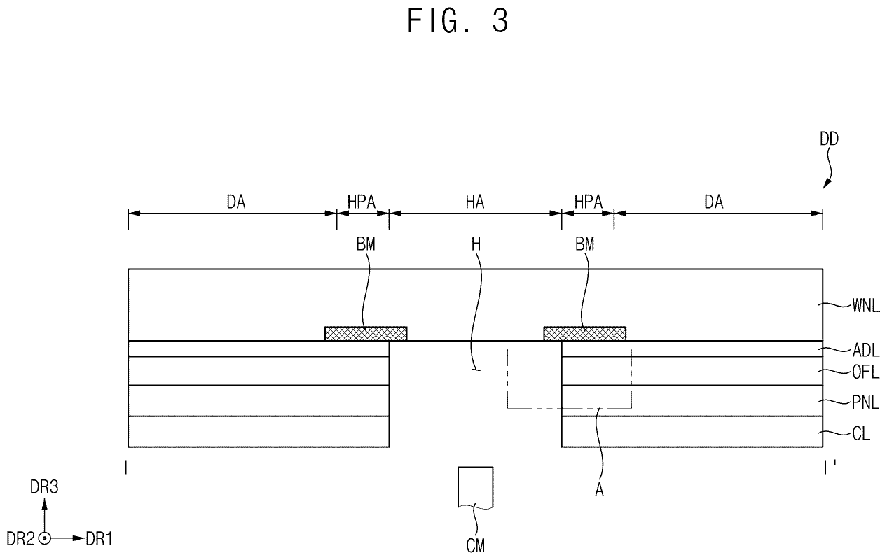

A hole area HA may be an area where an image may not be displayed and a component module (e.g., the component module CM in FIG. 3) that detects light received from the outside is disposed may be defined in at least a portion of the display area DA. The display area DA may surround at least a portion of the hole area HA. In addition, the hole area HA may be adjacent to the hole peripheral area HPA. Specifically, the hole peripheral area HPA may be disposed to surround the hole area HA, and the display area DA may be disposed to surround the hole peripheral area HPA.

In an embodiment, a shape of the hole area HA may be circular in a plan view. However, the present disclosure may not be limited to this embodiment, and the hole area HA may have various shapes in a plan view. In an embodiment, the hole area HA may be located in an upper right corner of the display device DD. In another embodiment, the hole area HA may be located in an upper left corner of the display device DD. In another embodiment, the hole area HA may be located in an upper center of the display device DD. In an embodiment, a plurality of wires may extend in the hole peripheral area HPA along an edge of the hole area HA. The plurality of wires extend through the hole peripheral area HPA to the display area DA and may be electrically connected to the pixel PX.

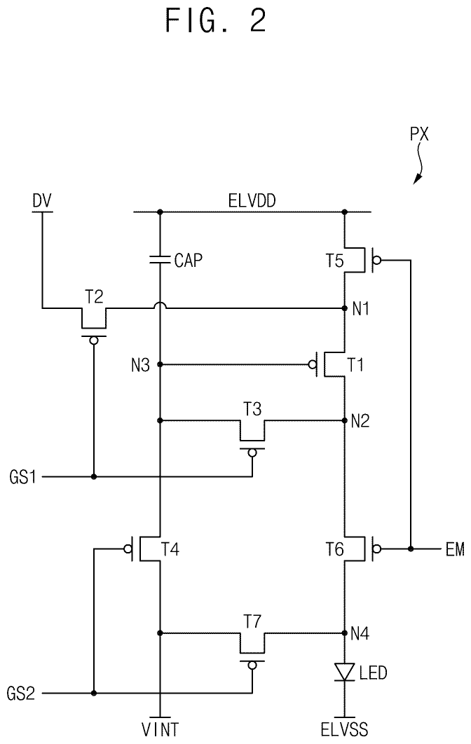

FIG. 2 is a circuit diagram illustrating a pixel included in the display device of FIG. 1.

Referring to FIG. 2, the pixel PX may include a first transistor T1, a second transistor T2, a third transistor T3, a fourth transistor T4, a fifth transistor T5, a sixth transistor T6, a seventh transistor T7, a capacitor CAP, and a light-emitting element LED.

The first transistor T1 may be connected between a first node N1 and a second node N2. The first transistor T1 may include a source electrode connected to the first node N1, a drain electrode connected to the second node N2, and a gate electrode connected to a third node N3.

The second transistor T2 may be connected between a data line and the first node N1. The second transistor T2 may include a source electrode receiving a data voltage DV, a drain electrode connected to the first node N1, and a gate electrode receiving a first gate signal GS1.

The third transistor T3 may be connected between the second node N2 and the third node N3. The third transistor T3 may include a source electrode connected to the third node N3, a drain electrode connected to the second node N2, and a gate electrode receiving the first gate signal GS1.

The fourth transistor T4 may be connected between an initialization voltage line and the third node N3. The fourth transistor T4 may include a source electrode receiving the initialization voltage VINT, a drain electrode connected to the third node N3, and a gate electrode receiving a second gate signal GS2.

The fifth transistor T5 may be connected between a first power supply that provides a high power voltage ELVDD and the first node N1. The fifth transistor T5 may include a source electrode that receives the high power voltage ELVDD, a drain electrode connected to the first node N1, and a gate electrode that receives a light-emitting control signal EM.

The sixth transistor T6 may be connected between the second node N2 and the fourth node N4. The sixth transistor T6 may include a source electrode connected to the second node N2, a drain electrode connected to a fourth node N4, and a gate electrode receiving a light-emitting control signal EM.

The seventh transistor T7 may be connected between the initialization voltage line and the fourth node N4. The seventh transistor T7 may include a source electrode receiving an initialization voltage VINT, a drain electrode connected to the fourth node N4, and a gate electrode receiving the second gate signal GS2.

The capacitor CAP may be connected between the first power supply and the third node N3. The capacitor CAP may include a first capacitor electrode connected to the third node N3 and a second capacitor electrode receiving the high power voltage ELVDD.

The light-emitting element LED may be connected between the fourth node N4 and a second power supply that provides a low power voltage ELVSS. The low supply voltage ELVSS may be lower than the high supply voltage ELVDD. The light-emitting element LED may include a first electrode connected to the fourth node N4 and a second electrode receiving the low power voltage ELVSS.

In an embodiment, each of the first, second, third, fourth, fifth, sixth, and seventh transistors T1, T2, T3, T4, T5, T6, and T7 may be a PMOS transistor. However, embodiments of the present disclosure may not be limited to this, and in another embodiment, at least one of the first, second, third, fourth, fifth, sixth, and seventh transistors T1, T2, T3, T4, T5, T6, and T7 may be an NMOS transistor.

In FIG. 2, the pixel PX is illustrated as including seven transistors and one capacitor, but embodiments of the present disclosure may not be limited this. For example, the pixel PX may include 2 to 6, or 8 or more transistors and two or more capacitors.

FIG. 3 is a cross-sectional view illustrating a cross-section taken along a line I-I′ of FIG. 1. FIG. 4 is a cross-sectional view illustrating an example of a cross-section of a display panel included in the display device of FIG. 1 in a display area.

Referring to FIGS. 3 and 4, the display device DD may include a display panel PNL, an optical function layer OFL, an adhesive layer ADL, a component module CM, a window layer WNL, a light-blocking member BM, and a lower cover layer CL. The display panel PNL may include a substrate SUB, a barrier layer BAR, a buffer layer BUF, a first insulating layer ILD1, a second insulating layer ILD2, an interlayer insulating layer ILD3, a transistor TR, a first organic layer VIA1, a first connection electrode CNE1, a second organic layer VIA2, a second connection electrode CNE2, a third organic layer VIA3, a pixel defining layer PDL, a spacer SPC, a light-emitting element LED, an encapsulation layer ENL, and a touch sensing layer TSL.

The transistor TR may include an active layer ACT, a gate electrode GE, a source electrode SE, and a drain electrode DE. The light-emitting element LED may include a pixel electrode PE, an light-emitting layer EML, and a common electrode CME. The touch sensing layer TSL may include a first touch insulating layer YILD1, a second touch insulating layer YILD2, a first touch electrode TE1, a third touch insulating layer YILD3, a second touch electrode TE2, and a touch protection layer YPVX.

The substrate SUB may serve as a base for the display panel PNL. The substrate SUB may include a transparent or opaque material. The substrate SUB may include a glass, a quartz, a plastic, and the like. For example, the plastic may include a polyimide, a polyethylene naphthalate, a polyethylene terephthalate, a polycarbonate, a polyetherimide, a polyethersulfone, and the like. These may be used alone or in combination with each other.

The barrier layer BAR may be disposed on the substrate SUB. The barrier layer BAR may reduce a moisture permeability of the substrate SUB and prevent foreign substances from diffusing into the light-emitting element LED. The barrier layer BAR may include an amorphous silicon, a silicon oxide, a silicon nitride, and the like. These may be used alone or in combination.

In FIG. 4, each of the substrate SUB and the barrier layer BAR is illustrated as a single-layer structure, but embodiments of the present disclosure may not be limited to the embodiment shown, and each or some of the substrate SUB and the barrier layer BAR may have a multi-layer structure. In addition, the substrate SUB and the barrier layer BAR may be alternatively stacked.

The buffer layer BUF may be disposed on the barrier layer BAR. The buffer layer BUF may prevent metal atoms or impurities from diffusing from the substrate SUB to the active layer ACT. In addition, the buffer layer BUF may control a heat transfer rate during a crystallization process to form the active layer ACT.

The first insulating layer ILD1 may be disposed on the buffer layer BUF. The first insulating layer ILD1 may include an inorganic insulating material. The inorganic insulating material may include silicon nitride, silicon oxide, silicon oxynitride, and the like. These may be used alone or in combination.

The active layer ACT may be disposed on the first insulating layer ILD1. The active layer ACT may include an amorphous silicon, a polycrystalline silicon, or an oxide semiconductor. The active layer ACT may include a source area and a drain area doped with impurities, and a channel area disposed between the source area and the drain area.

The second insulating layer ILD2 may be disposed on the first insulating layer ILD1. The second insulating layer ILD2 may cover the active layer ACT on the first insulating layer ILD1. For example, the second insulating layer ILD2 may have a substantially uniform thickness along the profile of the active layer ACT. Alternatively, the second insulating layer ILD2 may sufficiently cover the active layer ACT and may have a substantially flat upper surface without creating a step around the active layer ACT. The second insulating layer ILD2 may include an inorganic insulating material. The inorganic insulating material may include a silicon nitride, a silicon oxide, a silicon oxynitride, and the like. These may be used alone or in combination. As used herein, an “upper surface” of a structure is the surface of the structure that is farthest from the substrate SUB, and a “lower surface” of a structure is the surface of the structure that is closest to the substrate SUB.

The gate electrode GE may be disposed on the second insulating layer ILD2. The gate electrode GE may overlap the channel area of the active layer ACT. The gate electrode GE may include a metal, an alloy, a conductive metal oxide, a conductive metal nitride, a transparent conductive material, and the like.

The interlayer insulating layer ILD3 may be disposed on the second insulating layer ILD2. The interlayer insulating layer ILD3 may cover the gate electrode GE on the second insulating layer ILD2. For example, the interlayer insulating layer ILD3 may have a substantially uniform thickness along the profile of the gate electrode GE. Alternatively, the interlayer insulating layer ILD3 may sufficiently cover the gate electrode GE and may have a substantially flat upper surface without creating a step around the gate electrode GE.

In an embodiment, the interlayer insulating layer ILD3 may include an inorganic insulating material. The inorganic insulating material may include a silicon nitride, a silicon oxide, a silicon oxynitride, and the like. These may be used alone or in combination.

The source electrode SE and the drain electrode DE may be disposed on the interlayer insulating layer ILD3. The source electrode SE and the drain electrode DE may contact the active layer ACT through a contact hole penetrating the second insulating layer ILD2 and the interlayer insulating layer ILD3. For example, the source electrode SE may contact the source area of the active layer ACT, and the drain electrode DE may contact the drain area of the active layer ACT. Each of the source electrode SE and drain electrode DE may include a metal, an alloy, a conductive metal oxide, a conductive metal nitride, a transparent conductive material, and the like.

The first organic layer VIA1 may be disposed on the interlayer insulating layer ILD3. The first organic layer VIA1 may be disposed in the display area DA and the hole peripheral area HPA. The first organic layer VIA1 may have a substantially flat upper surface. In an embodiment, an opening that exposes a portion of an upper surface of the drain electrode DE may be defined in the first organic layer VIA1. In another embodiment, an opening that exposes a portion of an upper surface of the source electrode SE may be defined in the first organic layer VIA1. The first organic layer VIA1 may include an organic insulating material. For example, the organic insulating material may include an acrylic resin, an epoxy resin, a polyimide, a polyethylene, and the like. These may be used alone or in combination.

The first connection electrode CNE1 may be disposed on the first organic layer VIA1. In an embodiment, the first connection electrode CNE1 may contact the drain electrode DE through the opening exposing an upper surface of the drain electrode DE. In another embodiment, the first connection electrode CNE1 may contact the source electrode SE through the opening exposing an upper surface of the source electrode SE. The first connection electrode CNE1 may include a metal, an alloy, a conductive metal oxide, a conductive metal nitride, a transparent conductive material, and the like.

The second organic layer VIA2 may be disposed on the first organic layer VIA1. The second organic layer VIA2 may be disposed in the display area DA and the hole peripheral area HPA. The second organic layer VIA2 may have a substantially flat upper surface. An opening exposing a portion of an upper surface of the first connection electrode CNE1 may be defined in the second organic layer VIA2. The second organic layer VIA2 may include an organic insulating material. For example, the organic insulating material may include an acrylic resin, an epoxy resin, a polyimide, a polyethylene, and the like. These may be used alone or in combination.

The second connection electrode CNE2 may be disposed on the second organic layer VIA2. The second connection electrode CNE2 may contact the first connection electrode CNE1 through the opening defined in the second organic layer VIA2. The second connection electrode CNE2 may include a metal, an alloy, a conductive metal oxide, a conductive metal nitride, a transparent conductive material, and the like.

In an embodiment, the first connection electrode CNE1 and the second connection electrode CNE2 may physically and/or electrically connect the drain electrode DE and the pixel electrode PE. In another embodiment, the first connection electrode CNE1 and the second connection electrode CNE2 may physically and/or electrically connect the source electrode SE and the pixel electrode PE.

The third organic layer VIA3 may be disposed on the second organic layer VIA2. The third organic layer VIA3 may be disposed in the display area DA and the hole peripheral area HPA. The third organic layer VIA3 may have a substantially flat upper surface. An opening exposing a portion of the upper surface of the second connection electrode CNE2 may be defined in the third organic layer VIA3. The third organic layer VIA3 may include an organic insulating material. For example, the organic insulating material may include an acrylic resin, an epoxy resin, a polyimide, a polyethylene, and the like. These may be used alone or in combination.

The pixel electrode PE may be disposed on the third organic layer VIA3. The pixel electrode PE may contact the second connection electrode CNE2 through the opening defined in the third organic layer VIA3. The pixel electrode PE may include a metal, an alloy, conductive metal oxide, a conductive metal nitride, a transparent conductive material, and the like. These may be used alone or in combination. For example, the pixel electrode PE may include a silver and an indium tin oxide.

The pixel defining layer PDL may be disposed on the third organic layer VIA3. The pixel defining layer PDL may be disposed in the display area DA and the hole peripheral area HPA. The pixel defining layer PDL may partially cover the pixel electrode PE. In addition, an opening that exposes at least a portion of the pixel electrode PE may be defined in the pixel defining layer PDL. For example, the opening of the pixel defining layer PDL may expose a central portion of the pixel electrode PE, and the pixel defining layer PDL may cover an edges of the pixel electrode PE. The pixel defining layer PDL may include an organic insulating material such as a polyimide.

In an embodiment, the pixel defining layer PDL may include a light-blocking material. The light-blocking material may include carbon black, carbon nanotubes, a resin or a paste including black dye, metal particles, and the like. The metal particles may include a nickel, an aluminum, a molybdenum, a chromium, and the like. These may be used alone or in combination. When the pixel defining layer PDL includes the light-blocking material, external light reflection by metal structures (e.g., pixel electrode PE, and the like.) disposed under the pixel defining layer PDL may be reduced.

The spacer SPC may be disposed on the pixel defining layer PDL. In an embodiment, the spacer SPC may be formed together with the pixel defining layer PDL in a halftone mask process for manufacturing the display device DD. In an embodiment, the spacer SPC may include an organic insulating material or an inorganic insulating material. In an embodiment, the spacer SPC may include a different material from the pixel defining layer PDL.

The light-emitting layer EML may be disposed on the pixel electrode PE. For example, the light-emitting layer EML may be disposed on the pixel electrode PE exposed by the opening of the pixel defining layer PDL. The light-emitting layer EML may include an organic light-emitting material. The organic light-emitting material may include a low molecular weight organic compound or a high molecular weight organic compound. However, the present disclosure may not be limited to this, and the light-emitting layer EML may include materials such as quantum dots.

The common electrode CME may be disposed on the light-emitting layer EML. The common electrode CME may cover the light-emitting layer EML, the pixel defining layer PDL, and the spacer SPC. The common electrode CME may include a metal, an alloy, a conductive metal oxide, a conductive metal nitride, a transparent conductive material, and the like. For example, the common electrode CME may include aluminum, platinum, silver, magnesium, gold, chromium, tungsten, titanium, and the like. These may be used alone or in combination.

The encapsulation layer ENL may include a first encapsulation layer ENL1, a second encapsulation layer ENL2, and a third encapsulation layer ENL3. The first encapsulation layer ENL1 may be disposed on the common electrode CME. The first encapsulation layer ENL1 may cover the light-emitting element LED. The first encapsulation layer ENL1 may have a substantially uniform thickness along the profile of the common electrode CME. The first encapsulation layer ENL1 may include an inorganic insulating material. For example, the inorganic insulating material may include a silicon nitride, a silicon oxide, a silicon oxynitride, and the like. These may be used alone or in combination.

The second encapsulation layer ENL2 may be disposed on the first encapsulation layer ENL1. The second encapsulation layer ENL2 may not create a step around the first encapsulation layer ENL1 and may have a substantially flat upper surface. The second encapsulation layer ENL2 may include an organic insulating material. For example, the organic insulating material may include an acrylic resin, an epoxy resin, a polyimide, a polyethylene, and the like. These may be used alone or in combination.

The third encapsulation layer ENL3 may be disposed on the second encapsulation layer ENL2. The third encapsulation layer ENL3 may have a substantially uniform thickness and a substantially flat upper surface. The third encapsulation layer ENL3 may include an inorganic insulating material. For example, the inorganic insulating material may include a silicon nitride, a silicon oxide, a silicon oxynitride, and the like. These can be used alone or in combination. The encapsulation layer ENL may protect the light-emitting element LED from external impurities by sealing the display area DA.

The first touch insulating layer YILD1 may be disposed on the third encapsulation layer ENL3. The first touch insulating layer YILD1 may include an inorganic insulating material and/or an organic insulating material.

The second touch insulating layer YILD2 may be disposed on the first touch insulating layer YILD1. The second touch insulating layer YILD2 may cover the first touch insulating layer YILD1. The second touch insulating layer YILD2 may include an inorganic insulating material and/or an organic insulating material.

The first touch electrode TE1 may be disposed on the second touch insulating layer YILD2. The first touch electrode TE1 may include a metal oxide, a conductive metal nitride, a transparent conductive material, and the like. For example, the first touch electrode TE1 may include an aluminum, a copper, a titanium, a molybdenum, an indium tin oxide, and the like. These may be used alone or in combination. In an embodiment, the first touch electrode TE1 may have a single-layer structure. In another embodiment, the first touch electrode TE1 may have a multilayer structure.

The third touch insulating layer YILD3 may be disposed on the first touch electrode TE1. The third touch insulating layer YILD3 may cover the first touch electrode TE1. The third touch insulating layer YILD3 may include an inorganic insulating material and/or an organic insulating material.

The second touch electrode TE2 may be disposed on the third touch insulating layer YILD3. The second touch electrode TE2 may include a metal oxide, a conductive metal nitride, a transparent conductive material, and the like. For example, the second touch electrode TE2 may include an aluminum, a copper, a titanium, a molybdenum, an indium tin oxide, and the like. These may be used alone or in combination. In an embodiment, the second touch electrode TE2 may have a single-layer structure. In another embodiment, the second touch electrode TE2 may have a multilayer structure.

The touch protection layer YPVX may be disposed on the third touch insulating layer YILD3. The touch protection layer YPVX may cover the third touch insulating layer YILD3 and the second touch electrode TE2. The touch protection layer YPVX may include an organic insulating material.

The optical functional layer OFL may be disposed on the display panel PNL. The optical functional layer OFL may contact the touch sensitive layer TSL. Specifically, the optical functional layer OFL may be disposed on the touch protection layer YPVX. That is, a refractive layer with a high refractive index may not be disposed between the optical functional layer OFL and the touch protection layer YPVX.

The optical functional layer OFL may block external light incident on the display panel PNL. In an embodiment, the optical functional layer OFL may be a polarizing layer. The polarizing layer may be stretched in one direction. The direction in which the polarizing layer is stretched may be an absorption axis that absorbs light, and the direction perpendicular to the calculation direction may be a transmission axis that transmits light. However, the optical functional layer OFL according to embodiments of the present disclosure may not be limited to a polarizing layer, and the display device DD may have a structure that does not include a polarizing layer. In this case, the optical functional layer OFL may be a color filter or the like.

The adhesive layer ADL may be disposed on the optical functional layer OFL. The adhesive layer ADL can combine the optical function layer OFL and the window layer (WNL). In an embodiment, the adhesive layer ADL may include a pressure sensitive adhesive (PSA), an optically clear adhesive (OCA), an optically clear adhesive resin (OCR), etc. These can be used alone or in combination.

The lower cover layer CL may be disposed below the display panel PNL. The lower cover layer CL may support other components (e.g., display panel PNL, etc.) under the display device DD. The lower cover layer CL may include a metal, a glass, a polymer, and the like. The present disclosure may not be limited to this, and a housing covering a back of the display device DD and electronic components accommodated in the housing may be mounted under the lower cover layer CL.

A through hole H, penetrating the lower cover layer CL, the display panel PNL, the optical functional layer OFL, and the adhesive layer ADL, may be defined in the lower cover layer CL, the display panel PNL, the optical functional layer OFL, and the adhesive layer ADL. The hole area HA may be defined by the through hole H. The hole peripheral area HPA may be an area adjacent to an end of the through hole H. The lower cover layer CL, the display panel PNL, the optical function layer OFL, and the adhesive layer ADL may be disposed in the hole peripheral area HPA and the display area DA.

In an embodiment, a shape of the through hole H may be circular in a plan view. However, the present disclosure may not be limited to this, and a shape of the through hole H may be polygonal in a plan view.

The component module CM may be disposed under the lower cover layer CL corresponding to the hole area HA. The component module CM may receive the light passing through the hole area HA.

In an embodiment, examples of the component module CM may include a camera module, a face recognition sensor module, an iris recognition sensor module, an acceleration sensor module, a proximity sensor module, an infrared sensor module, and an illumination sensor module. The camera module may be a module that captures (or recognizes) an image of an object located in front of the display device. The facial recognition sensor module may be a module that detects the user's face. The iris recognition sensor module may be a module that detects the user's iris. The acceleration sensor module and the geomagnetic sensor module may be modules that determine movement of the display device. The proximity sensor module and the infrared sensor module may be modules that detect proximity to the front of the display device. The illuminance sensor module may be a module that measures the degree of external brightness.

The window layer WNL may be disposed on the adhesive layer ADL. The window layer WNL may be disposed in the hole area HA, the hole peripheral area HPA, and the display area DA. Specifically, the window layer WNL may be disposed over the hole area HA, the hole peripheral area HPA, the display area DA, and the non-display area (e.g., the non-display area NDA of FIG. 2).

In an embodiment, the window layer WNL may be ultra-thin glass. For example, the window layer WNL may include a soda lime glass, an alkali alumino silicate glass, a borosilicate glass, a lithium alumina silicate glass, and the like. These may be used alone or in combination. However, the window layer WNL of the present disclosure may not be limited to these materials and may include various materials such as a plastic.

The light-blocking member BM may be disposed on the adhesive layer ADL. The light-blocking member BM may be disposed in the hole area HA, the hole peripheral area HPA, and the display area DA. The light-blocking member BM may be disposed within the window layer WNL. The light-blocking member BM may be formed on the adhesive layer ADL. A hole passing through the hole area HA in the thickness direction may also be defined in the light-blocking member BM. The light-blocking member BM includes a light-blocking material such as carbon black, an organic pigment, and the like, accordingly the light-blocking member BM may block light.

In an embodiment, the light-blocking member BM may have a single-layer structure. With the single-layer structure, time and cost of manufacturing the display device DD may be reduced. However, the present disclosure may not be limited to this embodiment, and the light-blocking member BM according to embodiments of the present disclosure may have a multilayer structure.

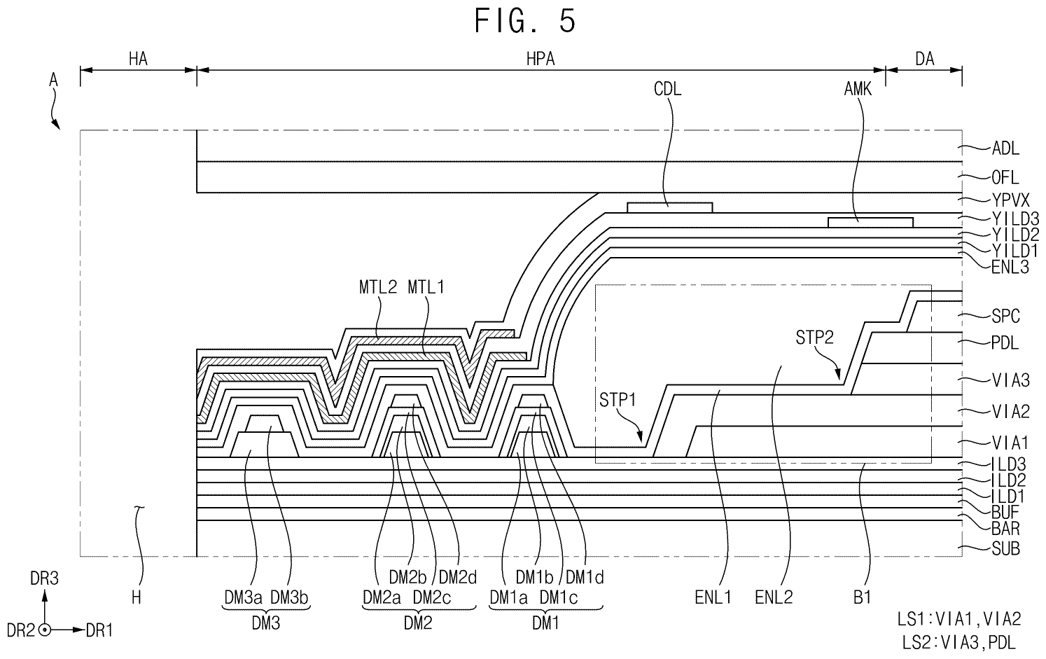

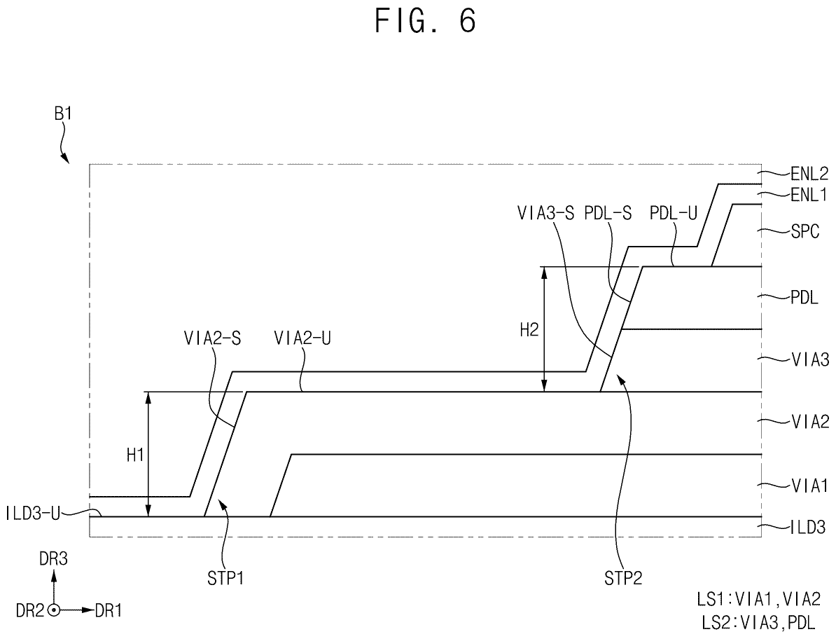

FIG. 5 is a cross-sectional view illustrating an example of a cross-section of area A of FIG. 3. FIG. 6 is a cross-sectional view illustrating a cross-section of area B1 of FIG. 5.

Referring to FIGS. 5 and 6, The display device (e.g., the display device DD of FIG. 1) includes first to third dams DM1, DM2, and DM3, a first metal layer MTL1, a second metal layer MTL2, and an alignment mark AMK, a crack detection layer CDL, a first stack structure LS1, and a second stack structure LS2.

The first to third dams DM1, DM2, and DM3 may be disposed in the hole peripheral area HPA on the interlayer insulating layer ILD3. The first, second, third dams DM1, DM2, and DM3 may be spaced apart from each other. The first dam DM1 may be located adjacent to the display area DA, and the third dam DM3 may be located adjacent to the hole area HA. In addition, the second dam DM2 may be located between the first dam DM1 and the third dam DM3.

In an embodiment, in a plan view, the third dam DM3 may surround the hole area HA, the second dam DM2 may surround the third dam DM3, and the first dam DM1 may surround the second dam.

The first dam DM1 may include a first portion DM1a, a second portion DM1b, a third portion DM1c, and a fourth portion DM1d. The first portion DM1a may be disposed on the interlayer insulating layer ILD3. The second portion DM1b may be disposed on the first portion DM1a. The third portion DM1c may be disposed on the second portion DM1b. The fourth portion DM1d may be disposed on the third portion DM1c.

The first portion DM1a may be formed through the same process as the second organic layer VIA2. In other words, the first portion DM1a may be disposed on the same layer as the second organic layer VIA2 and may include the same material.

The second portion DM1b may be formed through the same process as the third organic layer VIA3. In other words, the second portion DM1b may be disposed on the same layer as the third organic layer VIA3 and may include the same material as the third organic layer VIA3. The second portion DM1b may cover an upper surface and a side surface of the first portion DM1a. However, embodiments of the present disclosure may not be limited to this, and the second portion DM1b may cover an upper surface of the first portion DM1a.

The third portion DM1c may be formed through the same process as the pixel defining layer PDL. In other words, the third portion DM1c may be disposed on the same layer as the pixel defining layer PDL and may include the same material. The third portion DM1c may cover an upper surface and a side surface of the second portion DM1b. However, embodiments of the present disclosure may not be limited to this, and the third portion DM1c may cover an upper surface of the second portion DM1b.

The fourth portion DM1d may be formed through the same process as the spacer SPC. In other words, the fourth portion DM1d may be disposed on the same layer as the spacer SPC and may include the same material. The fourth portion DM1d may cover an upper surface of the third portion DM1c. However, embodiments of the present disclosure may not be limited to this, and the fourth portion DM1d may cover an upper surface and a side surface of the third portion DM1c.

The second dam DM2 may include a first portion DM2a, a second portion DM2b, a third portion DM2c, and a fourth portion DM2d. The first portion DM2a may be disposed on the interlayer insulating layer ILD3. The second portion DM2b may be disposed on the first portion DM2a. The third portion DM2c may be disposed on the second portion DM2b. The fourth portion DM2d may be disposed on the third portion DM2c.

The first portion DM2a may be formed through the same process as the second organic layer VIA2. In other words, the first portion DM2a may be disposed on the same layer as the second organic layer VIA2 and may include the same material as the second organic layer VIA2.

The second portion DM2b may be formed through the same process as the third organic layer VIA3. In other words, the second portion DM2b may be disposed on the same layer as the third organic layer VIA3 and may include the same material. The second portion DM2b may cover an upper surface and a side surface of the first portion DM2a. However, embodiments of the present disclosure may not be limited to this, and the second portion DM2b may cover an upper surface of the first portion DM2a.

The third portion DM2c may be formed through the same process as the pixel defining layer PDL. In other words, the third portion DM2c may be disposed on the same layer as the pixel defining layer PDL and may include the same material as the pixel defining layer PDL. The third portion DM2c may cover an upper surface and a side surface of the second portion DM2b. However, embodiments of the present disclosure may not be limited to this, and the third portion DM2c may cover an upper surface of the second portion DM2b.

The fourth portion DM2d may be formed through the same process as the spacer SPC. In other words, the fourth portion DM2d may be disposed on the same layer as the spacer SPC and may include the same material as the spacer SPC. The fourth portion DM2d may cover an upper surface of the third portion DM2c. However, embodiments of the present disclosure may not be limited to this, and the fourth portion DM2d may cover an upper surface and a side surface of the third portion DM2c.

The third dam DM3 may be adjacent to the hole area HA. For example, the third dam DM3 may be located closer to the hole area HA than the first and second dams DM1 and DM2. The third dam DM3 may include a first portion DM3a and a second portion DM3b. The first portion DM3a may be disposed on the interlayer insulating layer ILD3. The second portion DM3b may be disposed on the first portion DM3a. The first portion DM3a may be formed through the same process as the pixel defining layer PDL. In other words, the first portion DM3a may include the same material as the pixel defining layer PDL. The second portion DM3b may be formed through the same process as the spacer SPC. In other words, the second portion DM3b may be disposed on the same layer as the spacer SPC and may include the same material.

The first metal layer MTL1 and the second metal layer MTL2 may be disposed in the hole peripheral area HPA. Specifically, the first metal layer MTL1 and the second metal layer MTL2 may be located relatively closer to the hole area HA than the second encapsulation layer ENL2 within the hole peripheral area HPA. The first metal layer MTL1 and the second metal layer MTL2 may overlap the first to third dams DM1, DM2, and DM3.

The first metal layer MTL1 may be disposed on the second touch insulating layer YILD2. In an embodiment, the first metal layer MTL1 may be formed through the same process as the first touch electrode (e.g., the touch electrode TE1 of FIG. 4). In other words, the first metal layer MTL1 and the first touch electrode may be disposed on the same layer and include the same material. However, the present disclosure may not be limited to this, and the first metal layer MTL1 and the first touch electrode may include different materials from each other or may be disposed on different layers.

The second metal layer MTL2 may be disposed on the third touch insulating layer YILD3. In an embodiment, the second metal layer MTL2 may be formed through the same process as the second touch electrode (e.g., the touch electrode TE2 of FIG. 4). In other words, the second metal layer MTL2 and the second touch electrode may be disposed on the same layer and include the same material. However, the present disclosure may not be limited to this, and the second metal layer MTL2 and the second touch electrode may include different materials or may be disposed on different layers.

The alignment mark AMK and the crack detection layer CDL may overlap the second encapsulation layer ENL2. Specifically, the alignment mark AMK and the crack detection layer CDL may be disposed between the first dam DM1 and the display area DA. In other words, the alignment mark AMK and the crack detection layer CDL may not overlap the first, second, and third dams DM1, DM2, and DM3.

The alignment mark AMK may be disposed on the second touch insulating layer YILD2. The alignment mark AMK may be formed through the same process as the first touch electrode. In other words, the first metal layer MTL1 and the first touch electrode may be disposed on the same layer and include the same material. However, the present disclosure may not be limited to this arrangement, and the first metal layer MTL1 and the first touch electrode may include different materials from each other or may be disposed on different layers. The alignment mark AMK may improve the accuracy of a laser process for manufacturing a display device (e.g., the display device DD of FIG. 1) and reduce generation of cutting defects in the display device.

The crack detection layer CDL may be disposed on the third touch insulating layer YILD3. The crack detection layer CDL may be formed through the same process as the second touch electrode. In other words, the crack detection layer CDL and the second touch electrode may be disposed on the same layer and include the same material. The crack detection layer CDL may serve to detect cracks occurring in the hole peripheral area HPA of the display device.

The first and second stack structures LS1 and LS2 may be distanced from the first dam DM1 and the hole area HA. The first and second stack structures LS1 and LS2 may be arranged in the hole peripheral area HPA and the display area DA. The first stack structure LS1 may be disposed on the interlayer insulating layer ILD3. The second stack structure LS2 may be disposed on the first stack structure LS1.

The first stack structure LS1 may include the first organic layer VIA1 and the second organic layer VIA2. That is, the first stack structure LS1 may be spaced apart from the first dam DM1, may extend from the hole peripheral area HPA to the display area DA, and may be defined as a stack structure by the first organic layer VIA1 and the second organic layer VIA2.

A first stepped portion STP1 may be formed by the first stack structure LS1. Specifically, an upper surface VIA2-U of the second organic layer VIA2, a side VIA2-S facing the through hole H of the second organic layer VIA2, and an upper surface ILD3-U of the interlayer insulating layer ILD3 may together define the first stepped portion STP1.

The first stepped portion STP1 may be located in the hole peripheral area HPA. The first stepped portion STP1 may have a first height H1 in the hole peripheral area HPA. In an embodiment, the first height H1 may be about 2.8 μm or more, measured between the upper and lower surfaces of the first stack structure LS1 in the third direction DR3. For example, the first height H1 may be about 2.8 μm or more to about 4.0 μm.

The second stack structure LS2 may include a third organic layer VIA3 and a pixel defining layer PDL. That is, the second stack structure LS2 may be spaced apart from the first dam DM1 and extend from the hole peripheral area HPA to the display area DA. the second stack structure LS2 may be include the third organic layer VIA3 and the pixel defining layer PDL. A second stepped portion STP2 may be formed by the second stack structure LS2. Specifically, an upper surface PDL-U of the pixel defining layer PDL, a side surface VIA3-S facing the through hole H of the third organic layer VIA3, a side surface PDL-S facing the through hole H of the pixel defining layer PDL, and the upper surface VIA2-U of the second organic layer VIA2 together may define the second stepped portion STP2.

The second stepped portion STP2 may be located in the hole peripheral area HPA. The second stepped portion STP2 may have a second height H2 in the hole peripheral area HPA. In an embodiment, the second height H2 may be about 2.8 μm or more, measured between the two farthest surfaces of the second stack structure LS2 in the third direction DR3. Preferably, the second height H2 may be from about 2.8 μm or more to about 4.0 μm, inclusive.

In an embodiment, the first height H1 and the second height H2 may be substantially equal. In another embodiment, the first height H1 and the second height H2 may be different from each other. For example, the second height H2 may be greater than the first height H1. However, the present disclosure may not be limited to this, and the second height H2 may be smaller than the first height H1.

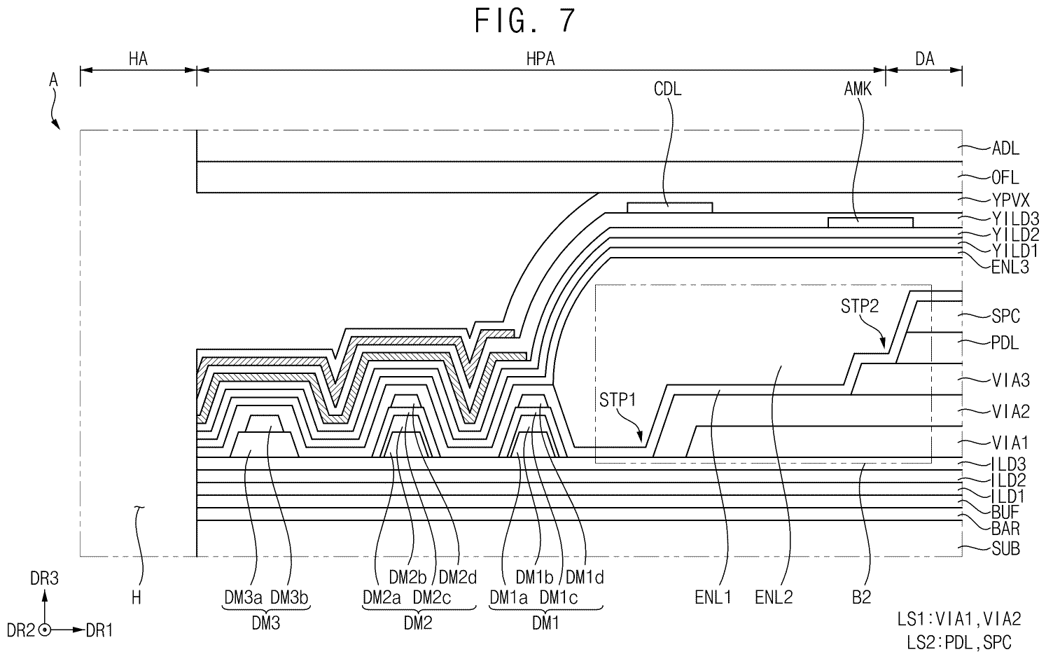

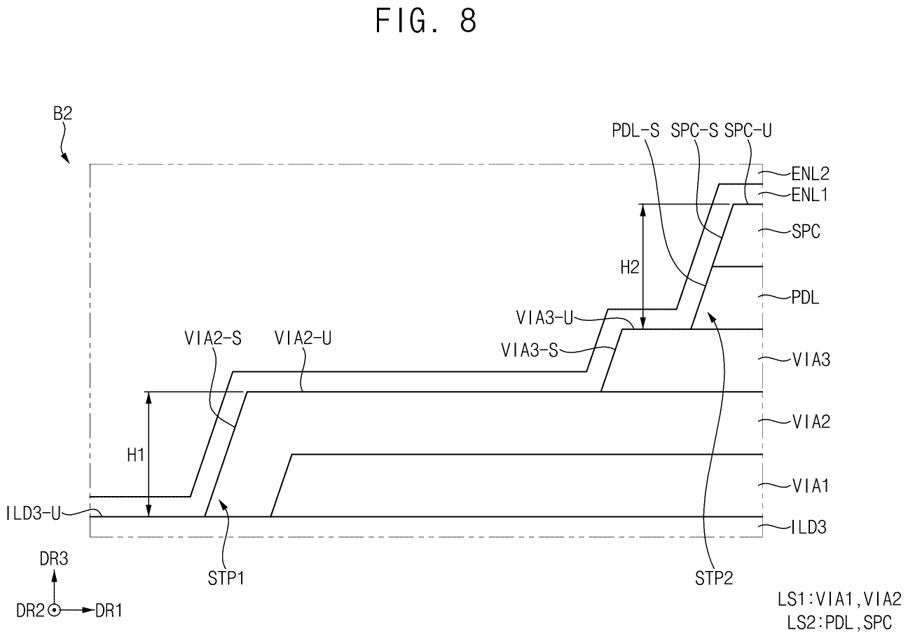

FIG. 7 is a cross-sectional view illustrating another example of a cross-section of area A of FIG. 3. FIG. 8 is a cross-sectional view illustrating a cross-section of area B2 of FIG. 7.

The display device described with reference to FIGS. 7 and 8 is substantially the same as the display device described with reference to FIGS. 5 and 6 except for the second stepped portion STP2. Hereinafter, content that overlaps with the content described in FIGS. 5 and 6 will be omitted or simplified.

Referring to FIGS. 7 and 8, the second stack structure LS2 may include a pixel defining layer PDL and a spacer SPC. That is, the second stack structure LS2 may be spaced apart from the first dam DM1 and extend from the hole peripheral area HPA to the display area DA. the second stack structure LS2 may include the pixel defining layer PDL and the spacer SPC. A second stepped portion STP2 may be defined by the second stack structure LS2. Specifically, an upper surface SPC-U of the spacer SPC, a side surface PDL-S facing the through hole H of the pixel defining layer PDL, and the side surface SPC-S facing the through hole H of the spacer SPC, and an upper surface VIA3-U of the third organic layer VIA3 may together define the second stepped portion STP2.

The third organic layer VIA3 may be disposed between the first stack structure LS1 and the second stack structure LS2. At least one extra stepped portion may also be defined by the third organic layer VIA3. The upper surface VIA3-U of the third organic layer VIA3, a side surface facing the through hole H of the third organic layer VIA3, and the upper surface VIA2-U of the second organic layer VIA2 may together define the stepped portion. In an embodiment, the height of the stepped portion may be smaller than the first height H1 and the second height H2.

The second stepped portion STP2 may be located in the display area DA. The second stepped portion STP2 may have a second height H2 in the display area DA. In an embodiment, the second height H2 may be about 2.8 μm or more, measured between the two farthest surfaces of the second stack structure LS2 in the third direction DR3. Preferably, the second height H2 may be from about 2.8 μm or more to about 4.0 μm. However, the second stepped portion STP2 according to embodiments of the present disclosure may not be limited to this, and the second stepped portion STP2 may be disposed in the hole peripheral area HPA.

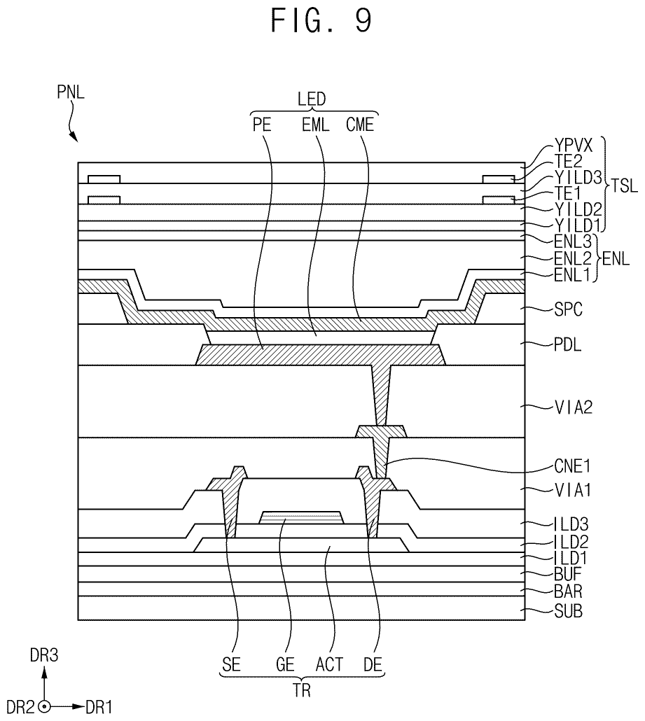

FIG. 9 is a cross-sectional view illustrating another example of a cross-section of a display panel included in the display device of FIG. 1 in a display area.

The display device described with reference to FIG. 9 is substantially the same as the display device described with reference to FIG. 4 except for the absence of the third organic layer VIA3 and the second connection electrode CNE2 of FIG. 4. Hereinafter, content that overlaps with the content described in FIG. 4 will be omitted or simplified.

Referring to FIG. 9, the pixel defining layer PDL may be disposed on the second organic layer VIA2. For example, the pixel defining layer PDL may partially cover the second organic layer VIA2. In other words, the third organic layer VIA3 and the second connection electrode CNE2 of FIG. 4 may not be disposed between the pixel defining layer PDL and the second organic layer VIA2. Accordingly, the pixel electrode PE may contact the first connection electrode CNE1 through the opening defined in the first organic layer VIA1.

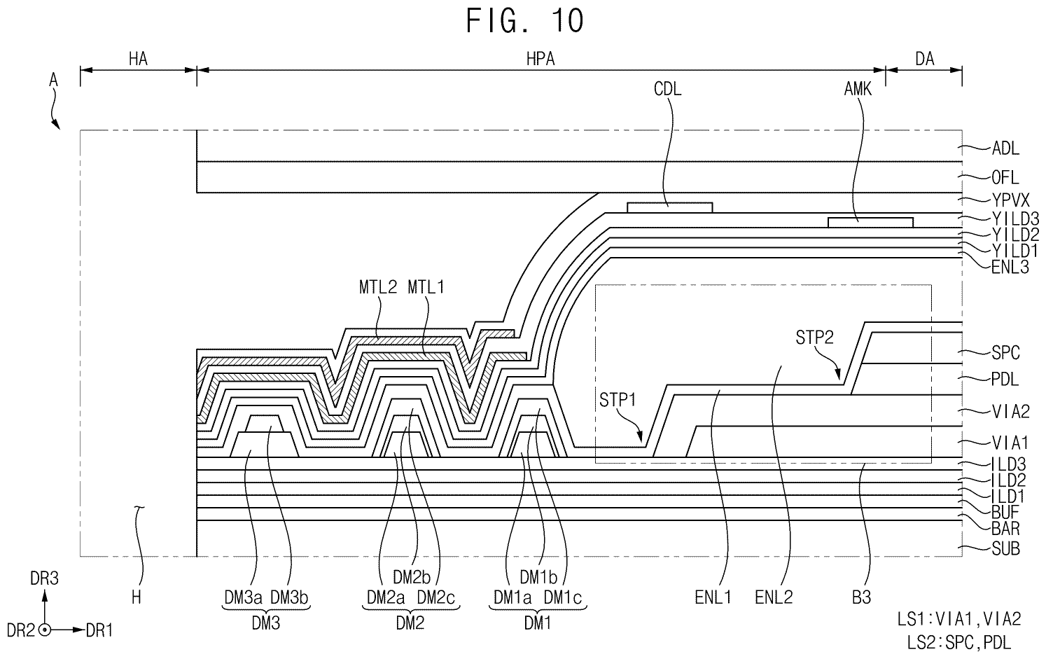

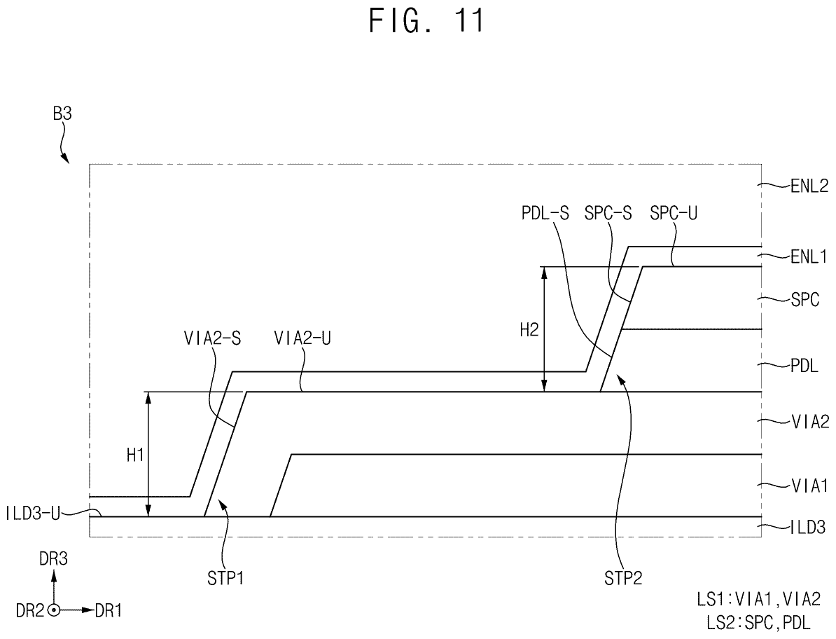

FIG. 10 is a cross-sectional view illustrating still another example of a cross-section of area A of FIG. 3. FIG. 11 is a cross-sectional view illustrating a cross-section of area B3 of FIG. 10.

The display device described with reference to FIGS. 10 and 11 is the same as the display device of FIGS. 5 and 11 except for the first, second third dams DM1, DM2, DM3, the third organic layer VIA3, and the second stepped portion STP2. Hereinafter, content that overlaps with the content described in FIGS. 5 and 6 will be omitted or simplified.

Referring to FIGS. 10 and 11, the first dam DM1 may include a first portion DM1a, a second portion DM1b, and a third portion DM1c. The first portion DM1a may be formed through the same process as the second organic layer VIA2. In other words, the first portion DM1a may be disposed on the same layer as the second organic layer VIA2 and may include the same material as the second organic layer VIA2. The second portion DM1b may be formed through the same process as the pixel defining layer PDL. In other words, the second portion DM1b may be disposed on the same layer as the pixel defining layer PDL and may include the same material as the pixel defining layer PDL. The third portion DM1c may be formed through the same process as the spacer SPC. In other words, the third portion DM1c may be disposed on the same layer as the spacer SPC and may include the same material as the spacer SPC.

The second dam DM2 may include a first portion DM2a, a second portion DM2b, and a third portion DM2c. The first portion DM2a may be formed through the same process as the second organic layer VIA2. In other words, the first portion DM2a may be disposed on the same layer as the second organic layer VIA2 and may include the same material as the second organic layer VIA2. The second portion DM2b may be formed through the same process as the pixel defining layer PDL. In other words, the second portion DM2b may be disposed on the same layer as the pixel defining layer PDL and may include the same material as the pixel defining layer PDL. The third portion DM2c may be formed through the same process as the spacer SPC. In other words, the third portion DM2c may be disposed on the same layer as the spacer SPC and may include the same material as the spacer SPC.

As described above, the pixel defining layer PDL may be disposed on the second organic layer VIA2. Accordingly, the embodiment of FIG. 10 does not have the third organic layer VIA3 that is disposed between the first stacked structure LS1 and the second stacked structure LS2 in the embodiment of FIG. 4.

The second stacked structure LS2 may include a pixel defining layer (PDL) and a spacer SPC. That is, the second stacked structure LS2 may be spaced apart from the first dam DM1 and extend from the hole peripheral area HPA to the display area DA. The second stacked structure LS2 may include the pixel defining layer PDL and the spacer SPC. A second stepped portion STP2 may be defined by the second stacked structure LS2. Specifically, an upper surface SPC-U of the spacer SPC, a side surface PDL-S facing the through hole H of the pixel defining layer PDL, and a side surface SPC-S facing the through hole H of the spacer SPC and the upper surface VIA2-U of the second organic layer VIA2 may together define the second stepped portion STP2.

As the spacer SPC is located in the display area DA, the second stepped portion STP2 may be located in the display area DA. The second stepped portion STP2 may have a second height H2 in the display area DA. In an embodiment, the second height H2 may be about 2.8 μm or more, measured between the two farthest surfaces of the second stack structure LS2 in the third direction DR3. The second height H2 may be from about 2.8 μm or more to about 4.0 μm. However, the second stepped portion STP2 according to embodiments of the present disclosure may not be limited to this, and the second stepped portion STP2 may be disposed in the hole peripheral area HPA.

As described above, the display device DD may include the first stack structure LS1 in which the first stepped portion STP1 having a first height H1 is defined in the hole peripheral area HPA and the second stack structure LS2 in which the second stepped portion STP2 having the second height H2 is defined in the display area DA or the hole peripheral area HPA.

When the height of at least one of the first height H1 of the first stepped portion STP1 and the second height H2 of the second stepped portion STP2 is less than about 2.8 μm, in the hole peripheral area HPA adjacent to the hole area HA, bubbles may be generated between the adhesive layer ADL and the optical functional layer OFL. Accordingly, the adhesive strength of the window layer WNL formed on the adhesive layer ADL may be compromised, sometimes resulting in a peeling of the window layer WNL.

The first height H1 of the first stepped portion STP1 and the second height H2 of the second stepped portion STP2 of the display device DD according to embodiments of the present disclosure may both be about 2.8 μm or more. Accordingly, an inclination angle of an side surface of the second encapsulation layer ENL2 facing the hole area HA may increase and become closer to vertical. Accordingly, an additional process of forming a member (e.g., a refractive layer with a high refractive index) to compensate for a step between the optical functional layer OFL and the touch sensing layer TSL may not be required, thereby process cost and time may be reduced. In addition, the light-blocking member BM may have a single-layer structure, which may further reduce process cost and time.

The display device according to the embodiment may be applied to various electronic devices. An electronic device according to an embodiment of the present disclosure may include the display device (e.g., the display device DD of FIG. 1) described above, and may further include modules or devices having additional functions in addition to the display device.

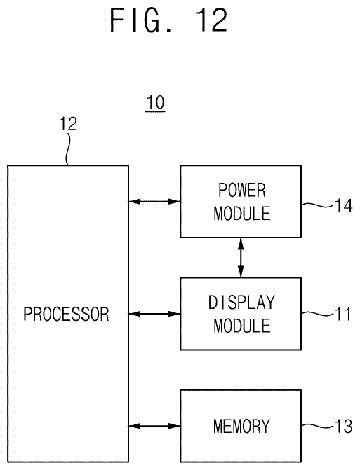

FIG. 12 is a block diagram of an electronic device according to an embodiment of the present disclosure.

Referring to FIG. 12, an electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal may be transmitted to the display module 11, and the display module 11 may process a signal received and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device according to the embodiments described above. In addition, a part among the individual modules functionally included in one module may be included in the display device, and another part may be provided separately from the display device. For example, the display device may include the display module 11, and the processor 12, the memory 13, and the power module 14 may be provided in the form of other devices within the electronic device 10 except for the display device.

In an embodiment, the display module 11 included in the display device may drive based on the image data signal and the input control signal received from the processor 12.

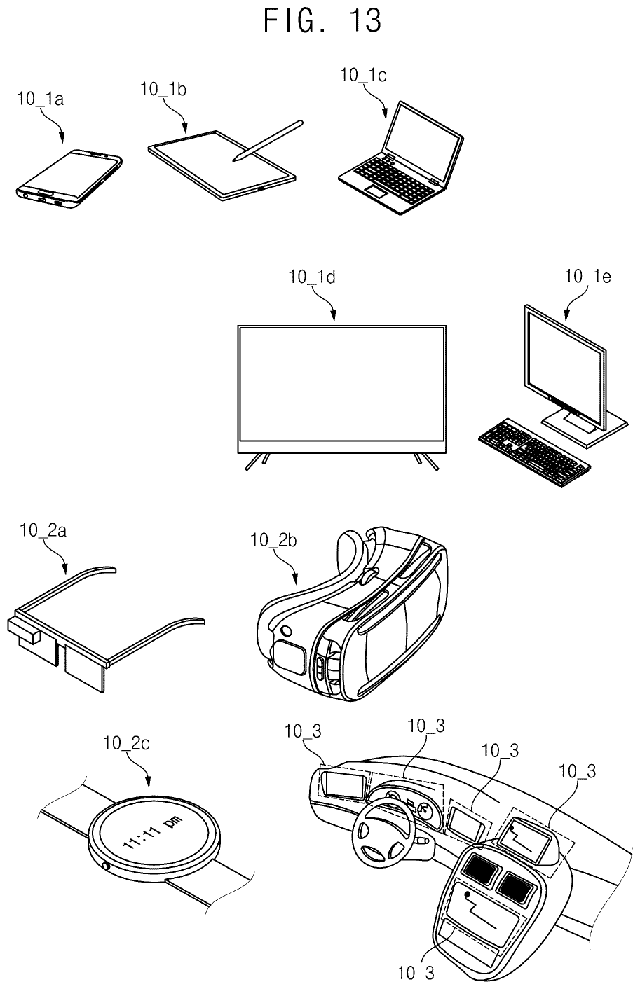

FIG. 13 is a schematic diagram of the electronic device according to various embodiments.

Referring to FIG. 13, various electronic devices to which display devices according to embodiments are applied may include not only image display electronic devices such as a smart phone 10_1a, a tablet PC 10_1b, a laptop 10_1c, a TV 10_1d, and a desk monitor 10_1e, but also a wearable electronic device including display modules such as smart glasses 10_2a, a head mounted display 10_2b, and a smart watch 10_2c, and a vehicle electronic device 10_3 including a dashboard, a center fascia, and display modules such as a CID (Center Information Display) and a room mirror display disposed in the dashboard.

The devices according to the embodiments may be applied to a display device included in a computer, a notebook, a mobile phone, a smartphone, a smart pad, a PMP, a PDA, an MP3 player, or the like.

Although the devices according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a substrate including a hole area that has a through-hole, a display area that surrounds at least a portion of the hole area, and a hole peripheral area disposed between the hole area and the display area;
an interlayer insulating layer disposed in the display area and the hole peripheral area on the substrate;
a first stack structure disposed on the interlayer insulating layer and forming a first stepped portion having a first height in the hole peripheral area, the first height being a distance between an upper surface and a lower surface of the first stack structure; and
a second stack structure disposed on the first stack structure and forming a second stepped portion having a second height of at least 2.8 μm and not exceeding 4.0 μm in the hole peripheral area and the display area, the second height being a distance between an upper surface and a lower surface of the second stack structure.

2. The display device of claim 1, wherein the first height is at least 2.8 μm and does not exceed 4.0 μm.

3. The display device of claim 1, wherein the first height and the second height are substantially equal to each other.

4. The display device of claim 1, wherein the first height and the second height are different from each other.

5. The display device of claim 1, further comprising:
a first organic layer disposed in the hole peripheral area and the display area on the interlayer insulating layer; and
a second organic layer disposed in the hole peripheral area and the display area on the first organic layer.

6. The display device of claim 5, wherein the first stack structure includes the first organic layer and the second organic layer, and
an upper surface of the second organic layer, a side surface of the second organic layer facing the hole area, and an upper surface of the interlayer insulating layer form the first stepped portion.

7. The display device of claim 5, further comprising:
a third organic layer disposed in the hole peripheral area and the display area on the second organic layer;
a pixel defining layer disposed on the third organic layer; and
a spacer disposed in the display area on the pixel defining layer.

8. The display device of claim 7, wherein the second stack structure includes the third organic layer and the pixel defining layer, and
an upper surface of the pixel defining layer, side surfaces of the third organic layer and pixel defining layer facing the hole area, and the upper surface of the second organic layer form the second stepped portion.

9. The display device of claim 7, wherein, the second stack structure includes the pixel defining layer and the spacer, and
an upper surface of the spacer and side surfaces of the pixel defining layer and the spacer facing the hole area, and an upper surface of the third organic layer form the second stepped portion.

10. The display device of claim 9, wherein the third organic layer is disposed between the first stack structure and the second stack structure.

11. The display device of claim 5, further comprising:
a pixel defining layer disposed in the display area on the second organic layer; and
a spacer disposed in the display area on the pixel defining layer.

12. The display device of claim 11, wherein the second stack structure includes the pixel defining layer and the spacer, and
an upper surface of the spacer, side surfaces of the pixel defining layer and the spacer facing the hole area, and the upper surface of the second organic layer form the second stepped portion.

13. The display device of claim 1, further comprising:
a touch sensing layer disposed in the display area and the hole peripheral area on the second stack structure;
an optical functional layer in the display area and the hole peripheral area on the touch sensing layer;
a window layer disposed in the hole area, the hole peripheral area, and the display area on the optical functional layer; and
a light-blocking member disposed in the window layer.

14. The display device of claim 13, wherein the light-blocking member has a single-layer structure.

15. The display device of claim 13, wherein the light-blocking member has a multi-layer structure.

16. The display device of claim 13, wherein the touch sensing layer contacts the optical functional layer.

17. A display device comprising:
a substrate including a hole area that has a through-hole, a display area that surrounds at least a portion of the hole area, and a hole peripheral area disposed between the hole area and the display area;
an interlayer insulating layer disposed in the hole peripheral area and the display area on the substrate;
a first organic layer disposed in the hole peripheral area and the display area on the interlayer insulating layer;
a second organic layer disposed in the hole peripheral area and the display area on the first organic layer;
a third organic layer disposed in the hole peripheral area and the display area on the second organic layer; and
a pixel defining layer disposed in the hole peripheral area and the display area on the third organic layer,
wherein an upper surface of the second organic layer, a side surface of the second organic layer covering the first organic layer, and an upper surface of the interlayer insulating layer form a first stepped portion, and
an upper surface of the pixel defining layer, side surfaces of the third organic layer and the pixel defining layer facing the hole area, and the upper surface of the second organic layer form a second stepped portion.

18. The display device of claim 17, wherein a height of each of the first stepped portion and the second stepped portion is at least 2.8 μm and does not exceed 4.0 μm.

19. A display device comprising:
a substrate including a hole area that has a through-hole, a display area that surrounds at least a portion of the hole area, and a hole peripheral area disposed between the hole area and the display area;
an interlayer insulating layer disposed in the hole peripheral area and the display area on the substrate;
a first organic layer disposed in the hole peripheral area and the display area on the interlayer insulating layer;
a second organic layer disposed in the hole peripheral area and the display area on the first organic layer;
a third organic layer disposed in the hole peripheral area and the display area on the second organic layer;
a pixel defining layer disposed in the hole peripheral area and the display area on the third organic layer; and
a spacer disposed in the display area on the pixel defining layer,
wherein an upper surface of the second organic layer, a side surface of the second organic layer covering the first organic layer, and an upper surface of the interlayer insulating layer form a first stepped portion, and
an upper surface of the spacer, side surfaces of the pixel defining layer and the spacer facing the hole area, and the upper surface of the third organic layer form a second stepped portion.

20. The display device of claim 19, wherein a height of each of the first stepped portion and the second stepped portion is at least 2.8 μm and does not exceed 4.0 μm.

21. An electronic device comprising:
a processor configured to output an image data signal and an input control signal; and
a display device configured to drive based on the image data signal and the input control signal, and including:
a substrate including a hole area that has a through-hole, a display area that surrounds at least a portion of the hole area, and a hole peripheral area disposed between the hole area and the display area;
an interlayer insulating layer disposed in the display area and the hole peripheral area on the substrate;
a first stack structure disposed on the interlayer insulating layer and forming a first stepped portion having a first height in the hole peripheral area, the first height being a distance between an upper surface and a lower surface of the first stack structure; and
a second stack structure disposed on the first stack structure and forming a second stepped portion having a second height of at least 2.8 μm and not exceeding 4.0 μm in the hole peripheral area and the display area, the second height being a distance between an upper surface and a lower surface of the second stack structure.
